(19) United States
(12) Patent Application Publication
(10) Pub. No.: US 2017/0163045 A1
(43) Pub. Date: Jun. 8, 2017

(54) COMBINATION RECEPTACLE AND WIRELESS POWER SYSTEM INCLUDING THE SAME

(71) Applicant: EATON CORPORATION, Cleveland, OH (US)

(72) Inventor: ASHWIN MICHAELRAJ, PEACHTREE CITY, GA (US)

(73) Assignee: EATON CORPORATION, CLEVELAND, OH (US)

(21) Appl. No.: 14/957,836

(22) Filed: Dec. 3, 2015

(51) Int. Cl. H02J 5/00; H05K 5/02

(52) U.S. Cl. CPC H02J 5/005; H05K 5/02

(57) ABSTRACT

A combination receptacle including a wireless power transmitter electrically coupled to a power source, wherein the wireless power transmitter is structured to receive power from the power source and to wirelessly transmit said power, a socket electrically coupled to the power source, wherein the socket is structured to receive power from the power source and to physically and electrically connect to a power cord to provide the power to a wired device electrically coupled to the power cord, and an enclosure structured to house the wireless power transmitter and the socket.

### BACKGROUND

Field

The disclosed concept relates generally to receptacles, and in particular, to receptacles for providing a combination of types of power. The disclosed concept also relates to wireless power systems.

Background Information

Electricity is often provided to electric devices via an electrical receptacle in the wall or floor of a room. Electrical receptacles are usually duplex-type electrical receptacles that include two sockets coupled together with a common housing. Each socket is able to electrically connect to and provide power to one power cord.

Some electric devices, such as phones, are able to be wirelessly charged via a wireless power receiver integrated into the device or an associated adapter. A wireless power receiver is configured to wirelessly receive power via inductive coupling from an associated wireless power transmitter. Prior wireless power transmitters have been sold as stand-alone devices, such as accessories for phones.

There is a co-existence of electric devices that are configured to receive power from a power cord or other type of wire and electric devices that are configured to receive power via wireless power transmission. There is a need to provide power for both of these types of electric devices.

There is room for improvement in receptacles.

There is also room for improvement in wireless power systems.

### SUMMARY

These needs and others are met by embodiments of the disclosed concept in which a combination receptacle includes a socket configured to provide wired power and a wireless power transmitter configured to wirelessly transmit power.

In accordance with one aspect of the disclosed concept, a combination receptacle, comprises: a wireless power transmitter electrically coupled to a power source, wherein the wireless power transmitter is structured to receive power from the power source and to wirelessly transmit said power; a socket electrically coupled to the power source, wherein the socket is structured to receive power from the power source and to physically and electrically connect to a power cord to provide the power to a wired device electrically coupled to the power cord; and an enclosure structured to house the wireless power transmitter and the socket.

In accordance with another aspect of the disclosed concept, a wireless power system, comprises: a power source; and a combination receptacle including: a wireless power transmitter electrically coupled to a power source, wherein the wireless power transmitter is structured to receive power from the power source and to wirelessly transmit said power; and a socket electrically coupled to the power source, wherein the socket is structured to receive power from the power source and to physically and electrically connect to a power cord to provide power via the power cord; and an enclosure structured to house the wireless power transmitter and the socket.

### BRIEF DESCRIPTION OF THE DRAWINGS

A full understanding of the disclosed concept can be gained from the following description of the preferred embodiments when read in conjunction with the accompanying drawings in which:

FIG. 1 is a schematic diagram of a wireless power system in accordance with an example embodiment of the disclosed concept;

FIG. 2 is a schematic diagram of a wireless power system in accordance with another example embodiment of the disclosed concept;

FIG. 3 is a schematic diagram of a wireless power transmitter and a wireless power receiver in accordance with an example embodiment of the disclosed concept;

FIG. 4 is an isometric view of a combination receptacle in accordance with an example embodiment of the disclosed concept;

FIG. 5 is a front view of a combination receptacle in accordance with an example embodiment of the disclosed concept; and

FIG. 6 is an isometric view of a wireless power transmitter in accordance with an example embodiment of the disclosed concept.

### DESCRIPTION OF THE PREFERRED EMBODIMENTS

Directional phrases used herein, such as, for example, left, right, front, back, top, bottom and derivatives thereof, relate to the orientation of the elements shown in the drawings and are not limiting upon the claims unless expressly recited therein.

As employed herein, the statement that two or more parts are “coupled” together shall mean that the parts are joined together either directly or joined through one or more intermediate parts.

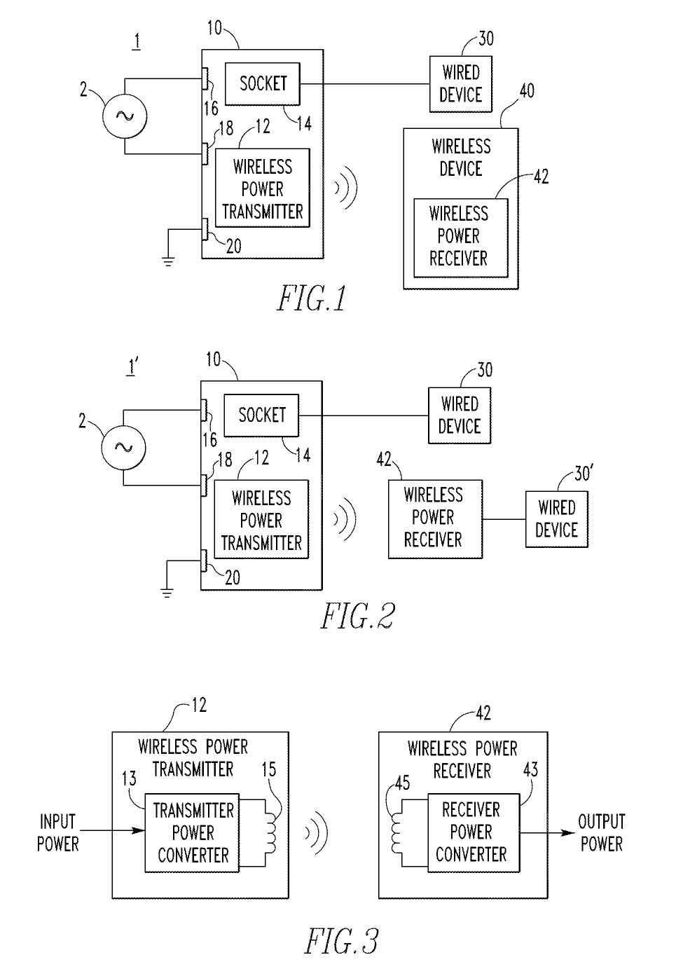

A schematic diagram of a wireless power system 1 in accordance with an example embodiment of the disclosed concept is shown in FIG. 1. The wireless power system 1 includes a combination receptacle 10 in accordance with an example embodiment of the disclosed concept.

The combination receptacle 10 is coupled to a power source 2 and is configured to receive power from the power source 2. In some example embodiments of the disclosed concept, the power source 2 is utility power such as, for example and without limitation, 120 VAC power that is common in residential and commercial establishments in the United States and other countries. However, it will be appreciated by those having ordinary skill in the art, that the power source 2 may be any other type of power or utility power without departing from the scope of the disclosed concept.

The combination receptacle 10 includes terminals 16, 18 and 20 configured to electrically couple the combination receptacle 10 to the power source 2 and ground. The terminals 16, 18 and 20 may include a line terminal 16, a neutral terminal 18 and a ground terminal 20. The terminals 16, 18 and 20 may be any type of terminal or wire connection, suitable to establish an electrical connection with a wire or another connector.

The combination receptacle 10 includes a wireless power transmitter 12 and a socket 14. Internal wiring (not shown) inside the combination receptacle 10 electrically connects the terminals 16, 18 and 20 to the wireless power transmitter 12 and the socket 14. The wireless power transmitter 12 and the socket 14 are configured to receive power from the power source 2 via the line and neutral terminals 16,18. The socket 14 is configured to receive an electrical plug or other type of connector and to create a wired electrical connection with a wired device 30. The socket 14 is configured to provide power from the power source 2 to the wired device 30 via the wired connection with the wired device 30. The wired device 30 may be any type of electrical device that it configured to receive power via a wired connection.

The wireless power transmitter 12 is configured to wirelessly transmit power that it has received from the power source 2. A wireless device 40 including a wireless receiver 42 configured to receive wirelessly transmitted power may receive the wireless power transmitted by the wireless power transmitter 12 and use it to power the wireless device 40. The wireless device 40 may be any type of device that is configured to receive and use wirelessly transmitted power such as, for example and without limitation, a smartphone.

In some example embodiments of the disclosed concept, such as the example wireless power system 1′ of FIG. 2, the wireless power receiver 42′ is not integrated into a wireless device. Rather, the wireless power receiver 42′ is configured to receive the wireless power transmitted by the wireless power transmitter 12 and provide it to a wired device 30′ via a wired connection such as, without limitation, a Universal Serial Bus (USB) connector or a Lightning connector. In some example embodiments of the disclosed concept, the wireless power receiver 42′ is an adapter configured for use with a smartphone and the wired device 30′ is a smartphone. However, it will be appreciated by those having ordinary skill in the art that the wireless power receiver 42′ and the wired device 30′ may be different combinations of devices without departing from the scope of the disclosed concept.

FIG. 3 is a more detailed schematic diagram of the wireless power transmitter 12 and the wireless power receiver 42 in accordance with an example embodiment of the disclosed concept. The wireless power transmitter 12 includes a transmitter power converter 13 and a transmitter coil 15. The transmitter power converter 13 is configured to receive input power from a power source such as the power source 2 shown in FIG. 1. The transmitter power converter 13 includes circuitry to convert the received input power to be wirelessly transmitted by the transmitter coil 15. The transmitter coil 15 is electrically connected to an output of the transmitter power converter 13 and is structured to receive and wirelessly transmit the power output from the transmitter power converter 13.

The wireless power receiver 42 includes a receiver power converter 43 and a receiver coil 45. The receiver coil 45 is structured to receiver the power transmitted by the transmitter coil 15 the wireless power transmitter 12. In more detail, the transmitter coil 15 and the receiver coil 45 become inductively coupled whereby current flowing through the transmitter coil 15 creates an electromagnetic field that induces current to flow through the receiver coil 45. The transmitter coil 15 and the receiver coil 45 may also be in resonance to help power flow in a loosely coupled system. The receiver power converter 43 is electrically connected to the receiver coil 45 and is structured to receive the output of the receiver coil 45. The receiver power converter 43 includes circuitry to convert the power received from the receiver coil 45 so that it can be output as output power that is useful for electrical devices such as the wireless device 40 of FIG. 1 or the wired device 30′ of FIG. 2.

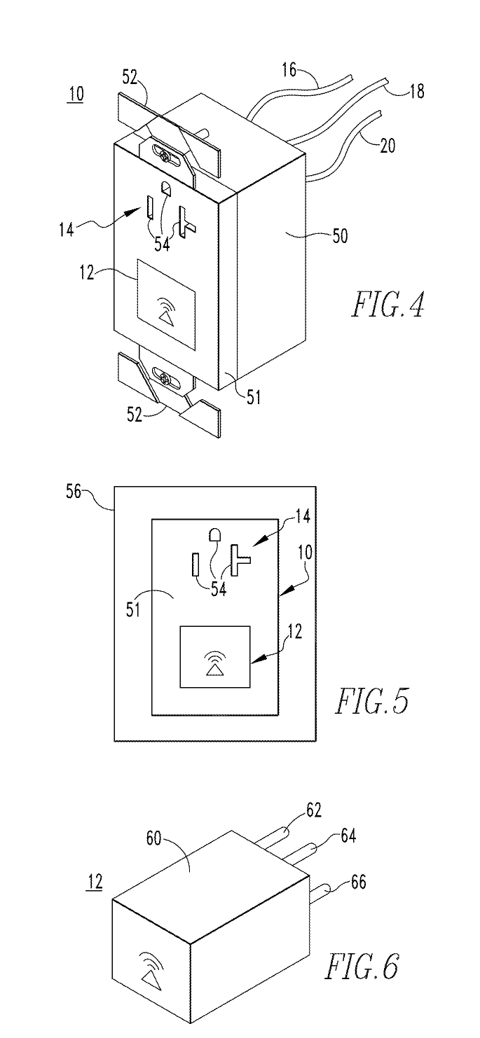

FIG. 4 is an isometric view of the combination receptacle 10 in accordance with an example embodiment of the disclosed concept. In the example shown in FIG. 4, the combination receptacle 10 includes an enclosure 50,51. The enclosure 50,51 houses the wireless power transmitter 12 and the socket 14 so as to create a single integrated device including both the wireless power transmitter 12 and the socket 14. The enclosure 50,51 includes a rear enclosure 50 and a front enclosure 51. The rear enclosure 51 is attached to the front enclosure 50 via mounting screws or other suitable fasteners (not shown). Also, in the example embodiment of the disclosed concept shown in FIG. 4, the terminals 16, 18 and 20 are wire leads extending from the rear enclosure 50. However, as previously described, the terminals 16, 18 and 20 may be any suitable type of device for establishing an electrical connection without departing from the scope of the disclosed concept.

In the example of FIG. 4, the combination receptacle 10 further includes a pair of brackets 52 coupled to the enclosure 50,51 at the top front and bottom front portions of the front enclosure 51. The brackets 52 are configured to allow the combination receptacle 10 to be installed in, for example, an electrical box.

In the example of FIG. 4, the socket 14 includes three openings 54 for receiving prongs of an electrical plug. However, it will be appreciated by those having ordinary skill in the art that any number and configuration of openings 54 may be employed in the socket 14 without departing from the scope of the disclosed concept.

FIG. 5 is a front view of the combination receptacle 10 in accordance with an example embodiment of the disclosed concept. In the example of FIG. 5, the combination receptacle 10 is shown installed in, for example and without limitation, an electrical box (not shown). An associated wall plate 56 is also coupled to the electrical wall plate so as to hide the brackets 52 (FIG. 4) of the combination receptacle 10 and provide an aesthetically pleasing installation.

FIG. 6 is an isometric view of the wireless power transmitter 12 in accordance with an example embodiment of the disclosed concept. In the example embodiment of the disclosed concept of FIG. 6, the wireless power transmitter 12 includes a housing 60 configured to house the components of the wireless power transmitter 12 such as the transmitter power converter 13 and the transmitter coil 15 (FIG. 3). The wireless power transmitter 12 also includes terminals 62, 64 and 66 (e.g., without limitation, wire leads) for electrically connecting the wireless power transmitter 12 to the terminals 16, 18 and 20 of the combination receptacle 10 so as to receive power from the power source 2 (FIG. 1).

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof.

What is claimed is:

1. A combination receptacle, comprising:
a wireless power transmitter electrically coupled to a power source, wherein the wireless power transmitter is structured to receive power from the power source and to wirelessly transmit said power;
a socket electrically coupled to the power source, wherein the socket is structured to receive power from the power source and to physically and electrically connect to a power cord to provide the power to a wired device electrically coupled to the power cord; and
an enclosure structured to house the wireless power transmitter and the socket.

2. The combination receptacle of claim 1, further comprising:
terminals structured to electrically couple to the power source,
wherein the wireless power transmitter and the socket are structured to receive power from the power source via the terminals.

3. The combination receptacle of claim 2, wherein the terminals are wire leads.

4. The combination receptacle of claim 1, wherein the wireless power transmitter includes transmitter coil and a transmitter power converter; and wherein the transmitter power converter is structured to convert the power from the power source for wireless transmission via the transmitter coil.

5. The combination receptacle of claim 4, wherein the wireless power transmitter includes a second enclosure structured to house the transmitter coil and the transmitter power converter.

6. The combination receptacle of claim 1, further comprising:
a pair of brackets coupled to the enclosure at a top portion thereof and a bottom portion thereof, respectively, and
wherein the pair of brackets are structured to couple the combination receptacle to an electrical box.

7. The combination receptacle of claim 1, wherein the power source is an alternating current power source.

8. The combination receptacle of claim 7, wherein the power source is a 120 VAC alternating current power source.

9. A wireless power system, comprising:
a power source; and
a combination receptacle including:
a wireless power transmitter electrically coupled to the power source, wherein the wireless power transmitter is structured to receive power from the power source and to wirelessly transmit said power;
a socket electrically coupled to the power source, wherein the socket is structured to receive power from the power source and to physically and electrically connect to a power cord to provide power via the power cord; and
an enclosure structured to house the wireless power transmitter and the socket.

10. The wireless power system of claim 9, further comprising:
a wired device structured to receive power from the socket via the power cord; and
a wireless device structured to receive power wirelessly transmitted from the wireless power transmitter, wherein the wireless device includes a wireless power transmitter integrated into the wireless device and being structured to receive the wireless power transmitted from the wireless power transmitter.

11. The wireless power system of claim 10, wherein the wireless device is a smartphone.

12. The wireless power system of claim 9, further comprising:
a first wired device structured to receive power from the socket via the power cord;
a wireless power receiver structured to receive the wireless power transmitted from the wireless power transmitted; and
a second wired device structured to electrically connect to the wireless receive power from the wireless receiver via a wired connection and to receive power from the wireless power receiver via the wired connection.

13. The wireless power system of claim 12, wherein the wired connection includes a universal serial bus connector or a lightning connector.

14. The wireless power system of claim 12, wherein the wireless power receiver is an adapter; and wherein the second wired device is a smartphone.

15. The wireless power system of claim 9, wherein the combination receptacle further comprises:
terminals structured to electrically couple to the power source, and
wherein the wireless power transmitter and the socket are structured to receive power from the power source via the terminals.

16. The wireless power system of claim 15, wherein the terminals are wire leads.

17. The wireless power system of claim 9, wherein the wireless power transmitter includes transmitter coil and a transmitter power converter; and wherein the transmitter power converter is structured to convert the power from the power source for wireless transmission via the transmitter coil.

18. The wireless power system of claim 17, wherein the wireless power transmitter includes a second enclosure structured to house the transmitter coil and the transmitter power converter.

19. The wireless power system of claim 9, wherein the combination receptacle of claim 1, further comprises:
a pair of brackets coupled to the enclosure at a top portion thereof and a bottom portion thereof, respectively,
wherein the pair of brackets are structured to couple the combination receptacle to an electrical box.

20. The wireless power system of claim 9, wherein the power source is an alternating current power source.
